(19) United States
(12) Patent Application Publication
(10) Pub. No.: US 2013/0314870 A1
(43) Pub. Date: Nov. 28, 2013

(54) HEAT DISSIPATION SYSTEM FOR POWER MODULE

(71) Applicants: Young Hoon KWAK, Suwon (KR); Kyu Hwan OH, Suwon (KR)

(72) Inventors: Young Hoon KWAK, Suwon (KR); Kyu Hwan OH, Suwon (KR)

(73) Assignee: SAMSUNG ELECTRO-MECHANICS CO., LTD., Gyunggi-do (KR)

(21) Appl. No.: 13/620,337

(22) Filed: Sep. 14, 2012

(30) Foreign Application Priority Data
May 23, 2012 (KR) 10-2012-0054753

(51) Int. Cl. F28F 1/00; H05K 7/20

(52) U.S. Cl. 361/689; 165/177

(57) ABSTRACT

Disclosed herein is a heat dissipation system for a power module, including: a manifold including an inlet and an outlet and formed so as to be opened at a surface thereof contacting a nozzle member; a nozzle member formed at an upper portion of the manifold and including inclined nozzles through which a cooling medium introduced through the inlet of the manifold passes; and a nozzle chamber formed on the nozzle member and forming a spacing space spaced from the nozzle member.

### CROSS REFERENCE TO RELATED APPLICATION

This application claims the benefit of Korean Patent Application No. 10-2012-0054753, filed on May 23, 2012, entitled “Heat Dissipation System for Power Module”, which is hereby incorporated by reference in its entirety into this application.

### BACKGROUND OF THE INVENTION

1. Technical Field

The present invention relates to a heat dissipation system for a power module.

2. Description of the Related Art

Currently, in order to dissipate heat of a power device (for example, an insulated gate bipolar mode transistor (IGBT), a diode, or the like) having a high heat generation amount, the power device has been bonded to a heat dissipation system by thermal grease or in an inter-metal bonding scheme.

Therefore, heat generated from the power device is dissipated through the heat dissipation system attached to the bottom surface.

In the above-mentioned heat dissipation system, an air cooling scheme or a water cooling scheme of using an aluminum heat sink, heat spreader, or heat pipe has been used.

### PRIOR ART DOCUMENT

### Patent Document

(Patent Document 1) US 2011-0017496 A

### SUMMARY OF THE INVENTION

The present invention has been made in an effort to provide a heat dissipation system for a power module capable of efficiently dissipating heat generated from a power module.

According to a preferred embodiment of the present invention, there is provided a heat dissipation system for a power module, including: a manifold including an inlet and an outlet and formed so as to be opened at a surface thereof contacting a nozzle member ; a nozzle member formed at an upper portion of the manifold and including inclined nozzles through which a cooling medium introduced through the inlet of the manifold passes; and a nozzle chamber formed on the nozzle member and forming a spacing space spaced from the nozzle member.

The manifold may further include a path part connected to the outlet to allow the cooling medium to flow.

The manifold may further include a plurality of partition walls formed to face each other at both sides of the path part based on the path part.

The nozzle member may further include a discharging hole formed in a form in which it penetrates through the nozzle member in a thickness direction so as to be connected to the path part of the manifold to allow the cooling medium sprayed through the nozzles to flow to the path part of the manifold.

The nozzles may include a plurality of nozzle rows, wherein the plurality of nozzle rows are formed to face each other based on the discharging hole.

The plurality of nozzle rows may be formed so that the respective nozzles in the nozzle row are disposed to be alternated with nozzles in other nozzle rows.

The nozzles may have a shape in which they are inclined toward a mounting region of a semiconductor device to be formed on the nozzle chamber.

The nozzle chamber may be formed so that sides in the spacing space are inclined.

The nozzle chamber may be made of a metal material.

The cooling medium may be cooling water, a refrigerant, or air.

The heat dissipation system may further include: an insulating layer formed on the nozzle chamber; and a semiconductor device formed on the insulating layer.

The heat dissipation system may further include a solder layer formed between the insulating layer and the semiconductor device.

According to another preferred embodiment of the present invention, there is provided a heat dissipation system for a power module including nozzles inclined toward a mounting region of a semiconductor device to spray a cooling medium through the nozzles.

The nozzles may include a plurality of nozzle rows, wherein the plurality of nozzle rows are formed so that the respective nozzles in the nozzle row are disposed to be alternated with nozzles in other nozzle rows.

The nozzles may have a shape in which they are inclined toward the mounting region of the semiconductor device.

The cooling medium may be cooling water, a refrigerant, or air.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a view showing a configuration of a heat dissipation system for a power module according to a preferred embodiment of the present invention in detail;

FIG. 2 is a view showing the configuration of the heat dissipation system for a power module taken along the line A-A′ of FIG. 1;

FIG. 3 is a view showing the configuration of the heat dissipation system for a power module taken along the line B-B′ of FIG. 1;

FIGS. 4 to 6 are views showing a configuration of a nozzle part according to the preferred embodiment of the present invention in detail;

FIGS. 7 to 9 are views showing a configuration of a nozzle chamber according to the preferred embodiment of the present invention in detail; and

FIGS. 10 and 11 are views describing a state in which the nozzle part and the nozzle chamber according to the preferred embodiment of the present invention are coupled to each other.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Heat Dissipation System for Power Module

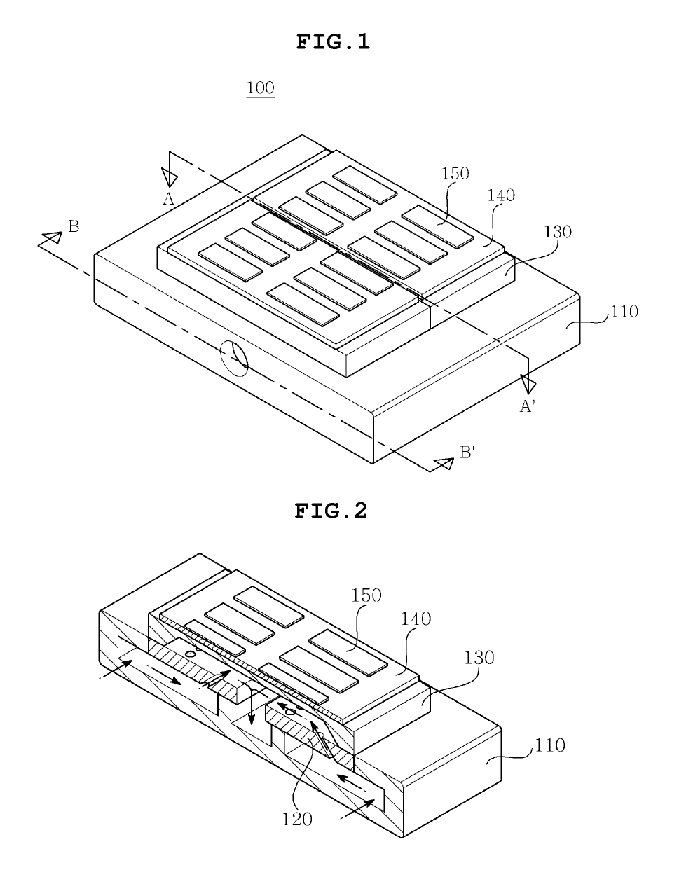

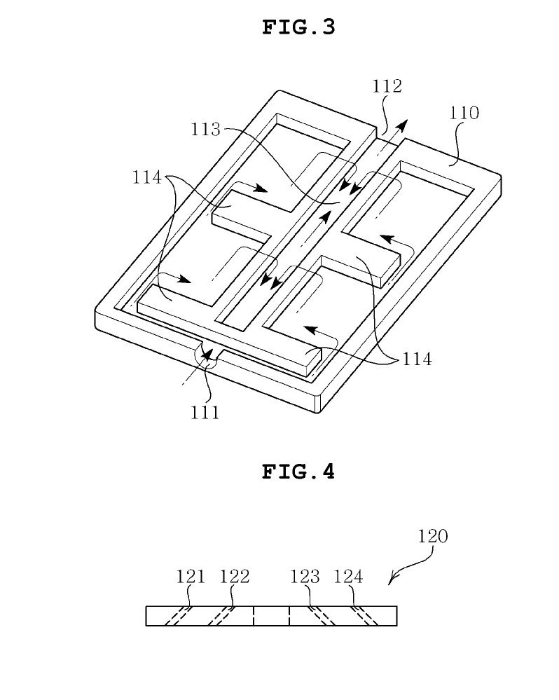

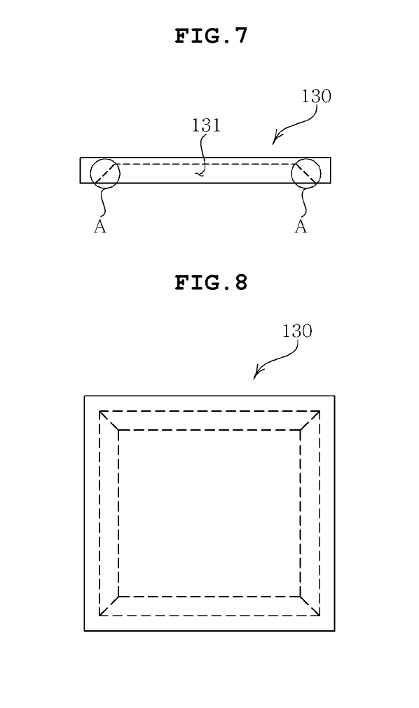

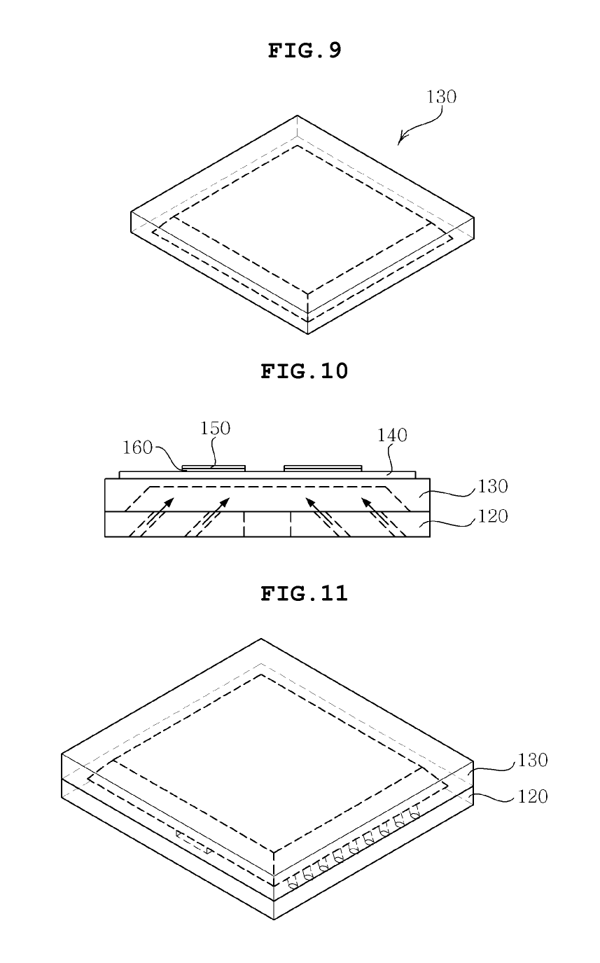

FIG. 1 is a view showing a configuration of a heat dissipation system for a power module according to a preferred embodiment of the present invention in detail; FIG. 2 is a cross-sectional view of the heat dissipation system for a power module taken along the line A-A’ of FIG. 1; FIG. 3 is a cross-sectional view of the heat dissipation system for a power module taken along the line B-B′ of FIG. 1; FIGS. 4 to 6 are views showing a configuration of a nozzle part according to the preferred embodiment of the present invention in detail; FIGS. 7 to 9 are views showing a configuration of a nozzle chamber according to the preferred embodiment of the present invention in detail; and FIGS. 10 and 11 are views describing a state in which the nozzle part and the nozzle chamber according to the preferred embodiment of the present invention are coupled to each other.

As shown in FIGS. 1, 4, and 10, the heat dissipation system 100 for a power module may include nozzles 121, 122, 123, and 124 that are inclined toward a mounting region of a semiconductor device to spray a cooling medium through the nozzles 121, 122, 123, and 124.

Here, the cooling medium may be cooling water, a refrigerant, or air, but is not limited thereto.

In more detail, the heat dissipation system 100 for a power module may include a manifold 110, a nozzle member 120, a nozzle chamber 130, an insulating layer 140, and a semiconductor device 150.

As shown in FIGS. 2 and 3, the manifold 110 may include an inlet 111 and an outlet 112 and may be formed so as to be opened at a surface thereof contacting the nozzle member 120.

In addition, the manifold 110 may further include a path part 113 connected to the outlet 112 to allow the cooling medium to flow.

Further, the manifold 110 may further include a plurality of partition walls 114 formed to face each other at both sides of the path part 113 based on the path part 113.

Here, as shown in FIG. 3, the number of partition walls 114 may be plural.

In addition, as shown in FIG. 3, since the partition walls 114 are formed to be spaced apart from both sides of the manifold 110, respectively, the cooling medium introduced through the inlet 114 flows between a sidewall and the partition wall of the manifold 110.

Further, since the plurality of partition walls 114 serve to divide the manifold 110 into a plurality of regions, the cooling medium may be smoothly distributed to the nozzle member 120 disposed on the manifold 110.

That is, due to the partition walls 114, a phenomenon that the cooling medium circulated in the heat dissipation system 100 for a power module is biased toward any one region may be prevented in advance.

As shown in FIGS. 4 to 6, the nozzle member 120 may be formed at an upper portion of the manifold 110 and include the inclined nozzles 121, 122, 123, and 124 through which the cooling medium introduced through the inlet 111 of the manifold 110 passes.

In addition, the nozzle member 120 may further include a discharging hole 125 formed in a form in which it penetrates through the nozzle member 120 in a thickness direction so as to be connected to the path part 113 of the manifold 110 to allow the cooling medium sprayed through the nozzles 121, 122, 123, and 124 to flow to the path part 113 of the manifold 110.

That is, as shown in FIGS. 2 and 3, the cooling medium is introduced through the inlet 11 of the manifold 110, sprayed to a spacing space of the nozzle chamber 130 through the nozzles 121, 122, 123, and 124 of the nozzle member 120, and then flows in a sequence of the discharging hole 125, the path part 113, and the outlet 112.

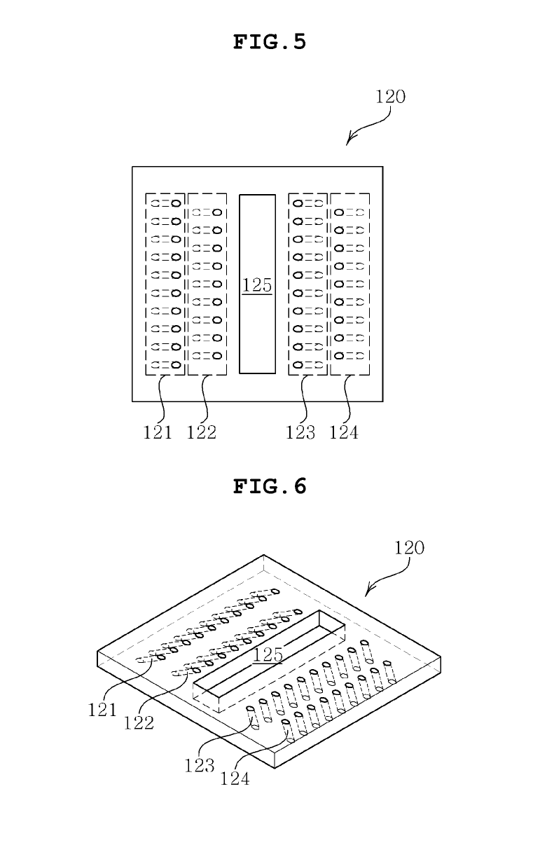

In addition, as shown in FIG. 5, the nozzles 121, 122, 123, and 124 may include a plurality of nozzle rows, wherein the plurality of nozzle rows may be formed to face each other based on the discharging hole 125.

In addition, the plurality of nozzle rows may be formed so that the respective nozzles in the nozzle row are disposed to be alternated with nozzles in other nozzle rows.

The disposition of the nozzles described above is to prevent path hindrance between the cooling media sprayed from the respective nozzles in a state in which the plurality of nozzle rows are formed in advance. In this disposition, since the sprayed cooling media do not contact each other and are thus sprayed up to the mounting region of the semiconductor device in a state in which their initial amount are maintained, heat dissipation efficiency may be improved.

In addition, the nozzles 121, 122, 123, and 124 may have a shape in which they are inclined toward the mounting region of the semiconductor device 150 to be formed on the nozzle chamber 130.

Since loss due to friction is less in the inclined structure of the nozzles 121, 122, 123, and 124 than in a vertical structure thereof at the time of spraying the cooling medium, the heat may be more efficiently dissipated from the semiconductor device 150.

As shown in FIGS. 1 and 7 to 9, the nozzle chamber 130 may be formed on the nozzle member 120 and form the spacing space spaced from the nozzle member 120.

In addition, the nozzle chamber 130 may be formed so that sides A (See FIG. 7) in the spacing space 131 are inclined.

Therefore, a phenomenon that the cooling medium sprayed from the nozzles 121, 122, 123, and 124 to the spacing space 131 of the nozzle chamber 130 contacts a region corresponding to the mounting region of the semiconductor device and then stays at an edge region of the spacing space 131 may be prevented.

In addition, the nozzle chamber 130 may be made of a metal material. For example, the nozzle chamber 130 may be made of a metal material having excellent heat dissipation characteristics, such as copper or aluminum, but is not limited thereto.

A state in which the nozzle member 120 and the nozzle chamber 130 are coupled to each other is shown in FIGS. 10 and 11.

In addition, the heat dissipation system 100 for a power module may include the insulating layer 140 formed on the nozzle chamber 130 and the semiconductor device 150 formed on the insulating layer 140.

Further, the heat dissipation system 100 for a power module may further include a solder layer 160 formed between the insulating layer 140 and the semiconductor device 150.

The heat dissipation system according to the preferred embodiment of the present invention may be applied to both of the water cooling type and air cooling type systems.

In addition, according to the preferred embodiment of the present invention, since high pressure and high speed cooling media are sprayed from the nozzles having an inclined angle and arranged in an asymmetric structure to directly collide with the mounting region of the semiconductor device while forming an inclined angle, a local heat dissipation effect is excellent

As set forth above, with the heat dissipation system for a power module according to the preferred embodiment of the present invention, the cooling medium is sprayed through the nozzles inclined toward the mounting region of the semiconductor device, thereby making it possible to efficiently dissipate the heat generated from the power module including the semiconductor device.

In addition, according to the preferred embodiment of the present invention, since the nozzles are inclined, when the sprayed cooling medium contacts the mounting region of the semiconductor device, the initial spraying force of the cooling medium is maintained, thereby making it possible to increase a heat dissipation effect.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A heat dissipation system for a power module, comprising:
a manifold including an inlet and an outlet and formed so as to be opened at a surface thereof contacting a nozzle member;
a nozzle member formed at an upper portion of the manifold and including inclined nozzles through which a cooling medium introduced through the inlet of the manifold passes; and
a nozzle chamber formed on the nozzle member and forming a spacing space spaced from the nozzle member.

2. The heat dissipation system as set forth in claim 1, wherein the manifold further includes a path part connected to the outlet to allow the cooling medium to flow.

3. The heat dissipation system as set forth in claim 2, wherein the manifold further includes a plurality of partition walls formed to face each other at both sides of the path part based on the path part.

4. The heat dissipation system as set forth in claim 1, wherein the nozzle member further includes a discharging hole formed in a form in which it penetrates through the nozzle member in a thickness direction so as to be connected to the path part of the manifold to allow the cooling medium sprayed through the nozzles to flow to the path part of the manifold.

5. The heat dissipation system as set forth in claim 4, wherein the nozzles include a plurality of nozzle rows, the plurality of nozzle rows being formed to face each other based on the discharging hole.

6. The heat dissipation system as set forth in claim 5, wherein the plurality of nozzle rows are formed so that the respective nozzles in the nozzle row are disposed to be alternated with nozzles in other nozzle rows.

7. The heat dissipation system as set forth in claim 1, wherein the nozzles have a shape in which they are inclined toward a mounting region of a semiconductor device to be formed on the nozzle chamber.

8. The heat dissipation system as set forth in claim 1, wherein the nozzle chamber is formed so that sides in the spacing space are inclined.

9. The heat dissipation system as set forth in claim 1, wherein the nozzle chamber is made of a metal material.

10. The heat dissipation system as set forth in claim 1, wherein the cooling medium is cooling water, a refrigerant, or air.

11. The heat dissipation system as set forth in claim 1, further comprising:
an insulating layer formed on the nozzle chamber; and
a semiconductor device formed on the insulating layer.

12. The heat dissipation system as set forth in claim 11, further comprising a solder layer formed between the insulating layer and the semiconductor device.

13. A heat dissipation system for a power module comprising nozzles inclined toward a mounting region of a semiconductor device to spray a cooling medium through the nozzles.

14. The heat dissipation system as set forth in claim 13, wherein the nozzles include a plurality of nozzle rows, the plurality of nozzle rows being formed so that the respective nozzles in the nozzle row are disposed to be alternated with nozzles in other nozzle rows.

15. The heat dissipation system as set forth in claim 13, wherein the nozzles have a shape in which they are inclined toward the mounting region of the semiconductor device.

16. The heat dissipation system as set forth in claim 13, wherein the cooling medium is cooling water, a refrigerant, or air.
